(19) United States
(12) Patent Application Publication
(10) Pub. No.: US 2003/0227967 A1
(43) Pub. Date: Dec. 11, 2003

(54) System and method for time-domain equalization in discrete multi-tone system

(76) Inventors: Chin-Liang Wang, Hsinchu (TW); Yuan-Shuo Chang, Hsinchu (TW); Chih-Ming Hsu, Hsinchu (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/162,914

(22) Filed: Jun. 6, 2002

(51) Int. Cl. H03H 7/30

(52) U.S. Cl. 375/229

(57) ABSTRACT

A novel structure for the TEQ in a DMT system receiver to shorten the length of the effective channel impulse response is provided. A time-domain equalizer, based on the decision-feedback filter structure, along with a training method is disclosed. In accordance with the DFE-based TEQ in the DMT system, the data symbols that transmitted through the effective shortened channel would be more reliable.

### BACKGROUND OF THE INVENTION

1. Field of Invention

The present invention relates generally to a Discrete Multi-tone (DMT) system that transmits data over digital subscriber lines, more particularly, to a Time-Domain Equalizer (TEQ) of a DMT system receiver.

2. Description of Prior Art

Owing to the widespread popularity of World Wide Web, Internet access market emerges and grows at an amazingly fast pace. Before the eventual full deployment of fiber for broadband access, telecommunications operators need to seek for alternative solutions to provide low-cost high-speed access networks. Thanks to the ubiquity of copper telephone lines, Asymmetric Digital Subscriber Line (ADSL) technology serves as an interim technology that can transform the legacy of twisted pair telephone lines to a high-speed data network.

ADSL systems use the Discrete Multi-tone (DMT) modulation as the underlying transmission technology. FIG. 1 is a block diagram showing the structure of a DMT system receiving apparatus.

The interface circuit 110 includes the circuits for separating DMT signals from the existing POTS signals, as well as other well-known circuitry components for interfacing to copper twisted-pair telephone lines. The analog signal at the output of interface circuit 110 is converted into digital samples by analog-to-digital converter (ADC) 120. These samples are processed by a Time-Domain Equalizer (TEQ) 130 to avoid intersymbol interference between adjacent DMT symbols. The samples at the output of TEQ 130 are further partitioned into a parallel form by Serial/Parallel converter (S/P) 140, wherein the boundary between adjacent DMT symbols is identified and a cyclic prefix is removed. It is noted that a cyclic prefix is a repetition of the last v samples of a DMT symbol and is appended to the beginning of the symbol where v is the predefined cyclic prefix length. A fast Fourier transform (FFT) circuit 145 then demodulates the partitioned digital samples into frequency domain values. These values are then passed through a frequency domain equalizer (FEQ) 150 and decoded by a Decoder 160 to recover the transmitted serial data stream.

For many multi-carrier transmission systems, a redundant sequence is inserted between the adjacent data symbols to overcome ISI problem. In ADSL transmission environment, a DMT symbol transmitted through the copper twisted-pair lines would be spanned extensively beyond its pre-defined interval to contaminate the next DMT symbols. Therefore, a lengthy overhead sequence, which, named cyclic prefix (CP) in ADSL systems, appended to the beginning of DMT symbols results in a significant data rate loss. In order to achieve reasonable efficiency, a time-domain equalizer (TEQ) 130 is used to shorten the overall channel response within a predefined length. With the TEQ 130 employed in the DMT systems, only fewer CP samples should be inserted between the DMT symbols, thereby improving the rate loss.

During an initialization procedure between two DMT transceivers, a training process is performed, by transmitting a signal x(t) known at the two transceivers through a channel 105 to obtain the parameters for related functional blocks.

In the prior art proposals for deriving the TEQ settings during the initialization procedure, an additional FIR filter called target impulse response (TIR) filter is employed to represent the effective shortened channel response. The main idea of this design method is based on minimizing the difference between the outputs of TEQ and TIR filters in the mean-squared error (MSE) sense. Among these MMSE (minimized mean-square error) TEQ approaches, an efficient training method was described in “Equalizer training algorithms for multicarrier modulation systems” by J. S. Chow et al., IEEE International Conference on Communications, pages 761-765, May 1993. Although the approach provides us an effective way to design the TEQ, the system performance may suffer significant degradation for some practical twisted-pair phone lines.

In this present invention, we employ the structure of decision-feedback equalizer to realize the functional block of TEQ in the DMT system. The novel structure of TEQ in our invention mainly consists of a feedforward filter and a feedback filter. Conceptually, the feedforward filter is a mean-square whitened matched filter (MS-WMF), which whitens the received noises and produces an overall effective channel response such that the output only has causal components. The feedback filter could reconstruct the residual causal ISI that remains unsuppressed after the received data being processed by the feedforward filter. Then the output of feedforward filter subtracts the output of feedback filter to cancel the excess ISI. Therefore, with the additional feedback filter being involved, more remaining ISI that cannot be removed by the traditional FIR filter is reduced to promote the overall system transmission performance. Moreover, an accompanying design method for this new structure of TEQ is proposed, which could obtain good TEQ settings while still keeping the computational complexity of design method efficient.

### SUMMARY OF THE INVENTION

A principal object of the present invention is to provide a structure of the Time-Domain Equalizer (TEQ) in the DMT system receiver by utilizing a decision-feedback equalizer (DFE), instead of the conventional FIR (finite impulse response) filter, so that the combined impulse response has a minimum length to avoid intersymbol interference between adjacent DMT symbols.

A further object of the present invention is to provide a training method for the DFE-based TEQ in the DMT system receiver by updating these filters in the frequency domain and delimiting them to have consecutive nonzero taps in the time domain.

In accordance with the objects of the present invention, a DFE-based time-domain equalizer (TEQ) in the DMT system has been achieved. The TEQ can shorten the length of the channel impulse response to be less than that of the cyclic prefix. The performance of the TEQ for a DMT-based ADSL system can be improved.

### BRIEF DESCRIPTION OF THE DRAWINGS

The present invention will be described in detail with reference to the accompanying drawings, wherein

FIG. 1 is a diagram of prior art showing a basic DMT structure

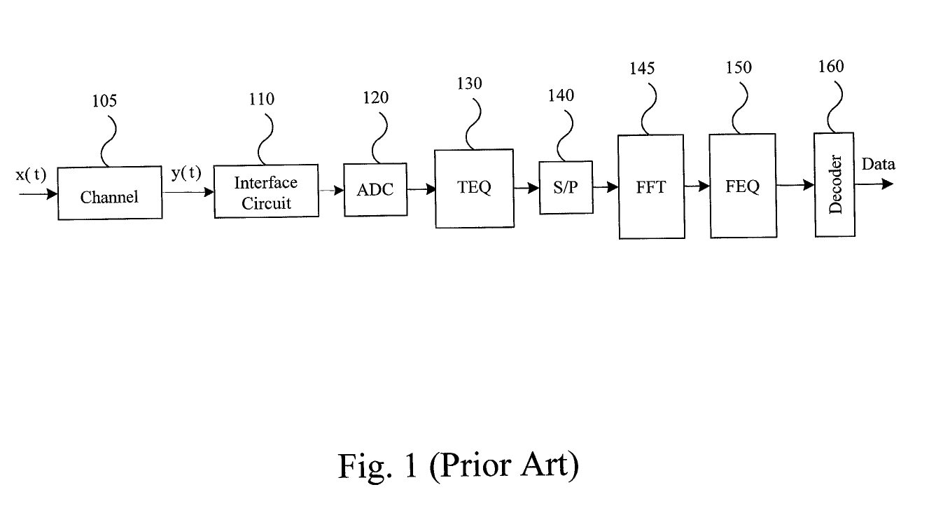

FIG. 2 is a diagram of the first preferred embodiment of the present invention;

FIG. 3 is a diagram of the second preferred embodiment of the present invention

FIG. 4 is a diagram for explaining the training method of TEQ in the two preferred embodiments of the invention;

FIG. 5 is a flow chart form of a preferred TEQ training process of the present invention;

FIG. 6 is a diagram for explaining the updating step for the TIR filter in the present training method;

FIG. 7 is a flow chart for depicting the windowing operation on the TIR filter in the present training method

FIG. 8 is a diagram for illustrating the updating step for the feedforward and feedback filters in the present training method; and

FIG. 9 is a flow chart for depicting the windowing operation on the feedforward and feedback filters in the present training method.

### DETAILED DESCRIPTION OF THE INVENTION

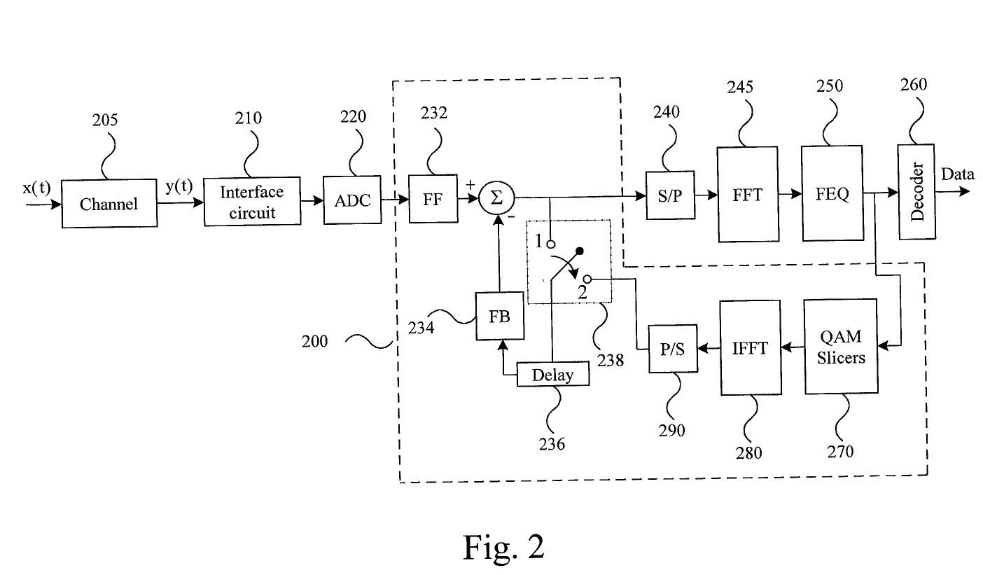

FIG. 2 illustrates a first preferred embodiment of the present invention. A time-domain equalizer (TEQ) system 200 comprises QAM slicers 270 for converting the outputs of FEQ 250 to the corresponding signal in the QAM constellation for each subcarrier, an IFFT 280 for inverse fast Fourier transforming data generated by QAM slicers 270, a Parallel/Serial converter (P/S) 290 for converting the IFFT output data into a serial 20 form, a feedforward filter (FF) 232 for whitening the received noises and producing an overall effective channel response such that the output only has causal components, a feedback filter (FB) 234 for reconstructing the residual causal ISI by using the past decisions, a delay line 236 for buffering the signals to the input of the feedback filter 234, and a switch 238 for connecting the input end of delay line 236 to the first node 1 or the second node 2.

The timing for whichever be connected is described as following

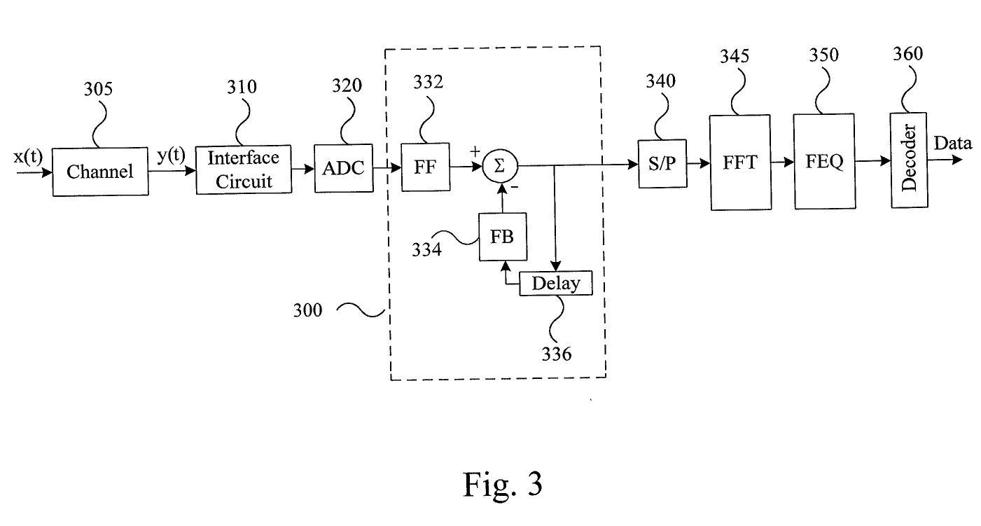

First, assume that at time n the rear v samples of last demodulated DMT symbol has been fed back to the second node 2 in time before a new digital sample of next DMT symbol being processed by the feedforward filter 232. Herein the parameter v is the length of cyclic prefix. Then during the interval of time n+1 to n+v, the feedforward filter 232 continues processing the incoming digital samples at the ADC output and meantime the input end of delay line should be connected to the second node 2 for feeding the rear v samples of last demodulated DMT symbol already here back to the input of feedback filter. After time n+v, the input end of delay line should be switched to the first node 1 for importing the feedback filter directly from the samples at the input of serial/parallel converter until a new complete DMT symbol be collected at the input of FFT. Again the v rear samples of current DMT symbol are reproduced at the second node 2 and the above operations will be followed repeatedly for the coming DMT symbols. Note that the input end of delay line 236 could be connected to the first node 1 where these samples are yet unperformed by the QAM slicers 270 is under the assumption that the TEQ settings are well obtained by the present training method during the initialization procedure. However, this TEQ structure requires large computation resources, an alternative structure for TEQ is proposed as our second preferred embodiment of the present invention. FIG. 3 illustrates a second preferred embodiment of the present invention. A time-domain equalizer (TEQ) 300 comprises a feedforward filter (FF) 332 for whitening the received noises and producing an overall effective channel response such that the output only has causal components, a feedback filter (FB) 334 for reconstructing the residual causal ISI by using the past decisions, and a delay line 336 for buffering the signals to the input of the feedback filter 334.

In the second preferred embodiment of the present invention, the time-domain equalizer (TEQ) 300 reduces the computational complexity of the time-domain equalizer (TEQ) 200 of the first preferred embodiment of the present invention dramatically at the cost of slight performance degradation.

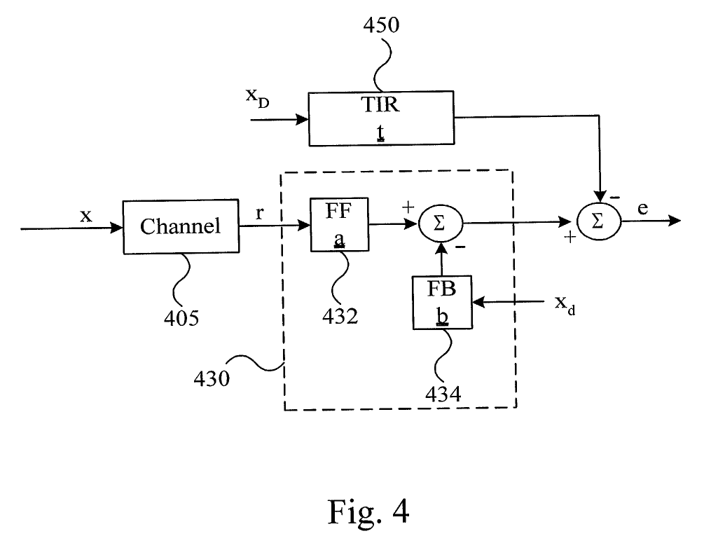

A diagram for explaining the training method of TEQ in the two preferred embodiments (the time-domain equalizer (TEQ) 200 and 300) of the present invention is shown in FIG. 4. The training data denotes x, the number of taps in feedforward filter (FF) 432 denotes Nₐ, the number of taps in feedback filter (FB) 434 denotes N_{b}, and the number of taps in TIR filter 450 denotes Nₜ. Then, the column vectors are defined that a=[a(0), a(1), . . . , a(Nₐ−1)], b=[b(0), b(1), . . . , b(N_{b}−1)], and t=[t(0), t(1), . . . , t(Nₜ−1)], where a, b and t denote the taps of FF 432, FB 434 and TIR filters 450 respectively.

The training data consisting of a sufficient number of identical DMT symbols is passed through a twisted-pair telephone line channel 405. Due to the periodic nature of the training data, the received data is also periodic and can be obtained by cyclically convoluting x and the impulse response h of the channel 405. (This property implies the equivalent multiplication in frequency domain) The received data r is used as input data for feedforward filter (FF) 432. The input data x_{d} of feedback filter (FB) 434 is the training data x delayed by d samples. A Target Impulse Response (TIR) filter 450 is employed to speed up the convergence of TEQ filter 430. The input data X_{D} for TIR filter 450 is the training data x delayed by D samples.

The filter coefficients of feedforward filter 432 and feedback filter 434 are adjusted to minimize the mean-square error between the outputs of TEQ filter 430 and TIR filter 450.

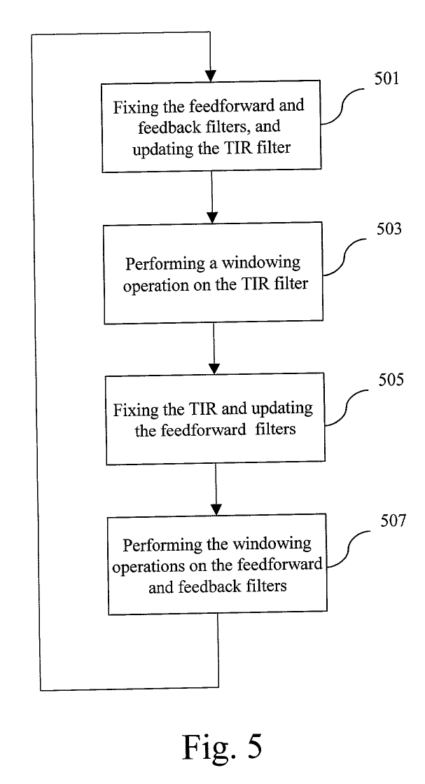

FIG. 5 is a flow chart form of a preferred TEQ training process of the present invention. The training process comprises the steps:

501: fixing the feedforward and feedback filters and then updating the TIR filter in the frequency domain by the FLMS (frequency-domain least mean-square) method;

503: performing a windowing operation on the TIR in the time domain to limit the taps outside the window of length v+1 to be zeros;

505: fixing the TIR and then update the feedforward and feedback filter in the frequency domain by the FLMS (frequency-domain least mean-square) method; and

507: performing the windowing operations on the feedforward and feedback filters in the time domain to limit them to only have Nₐ and N_{b} consecutive non-zero taps respectively, then returning to the step 501.

The above steps are repeated until the training period has been expired.

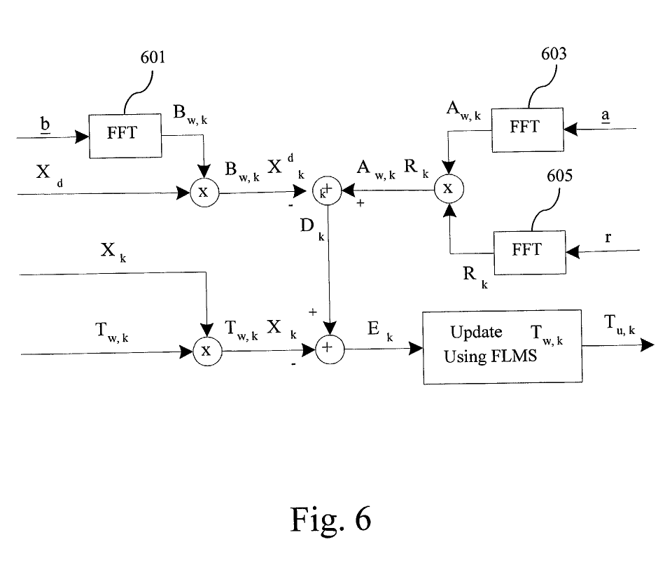

A diagram for explaining the updating step 501 for the TIR filter in the present training method is shown in FIG. 6. Since the updating operation 501 for the TIR filter is performed in the frequency domain, the coefficients of feedforward, feedback and TIR filters should be transformed into the frequency domain first. Accordingly, the length of the column vectors a, b, and t would be extended to the FFT size by appending sufficient zeros behind them, and then taking its FFT, respectively. Hence the taps of feedforward, feedback and TIR filters are converted by FFTs and then result in the corresponding sets of frequency samples A_{w,k}, B_{w,k}, and T_{w,k}, where the lower script w represents the filter that has been windowed and k represents the subcarrier index. Similarly, the training data x, the input data of feedback filter x_{d} and the received data r are transformed into the frequency samples of Xₖ, X^{d}ₖ and Rₖ as well. Then the output frequency samples of feedforward, feedback, and TIR filters could be generated by multiplying A_{w,k} with Rₖ, B_{w,k} with X^{d}ₖ and T_{w,k} with Xₖ, respectively. The output frequency samples of feedforward filter subtract the output frequency samples of feedback filter as the desired signals and are shown in the following equation [1]:

Dₖ=A_{w,k}Rₖ−B_{w,k}X^{d}ₖ [1]

And further the error signals would be obtained as the following equation [2]:

Eₖ=Dₖ−T_{w,k}Xₖ [2]

Eventually, the taps of TIR filter in the frequency domain are updated by the following equation [3];

T_{u,k}=T_{w,k}+αEₖX*ₖ [3]

where the lower script u represents that the TIR filter remains unwindowed, α is the step size, and X*ₖ is the complex-conjugate value of Xₖ.

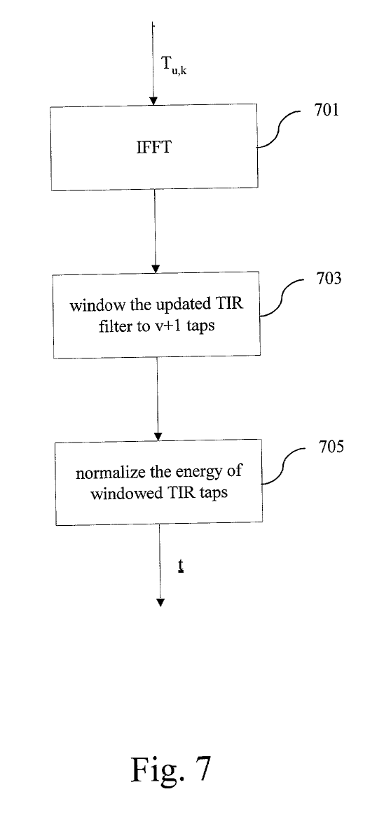

FIG. 7 is a flow chart for depicting the windowing operation 503 on the TIR filter. Because the windowing operation is performed in the time domain, the frequency taps of updated TIR filter, T_{u,k}, should be transformed to the time-domain taps by IFFT . Then the time-domain taps of TIR filters would be limited to v+1 consecutive samples by placing a fixed window on it. The starting position of the window of length v+1 is set to align with the tap of TIR filter that corresponding to the channel delay and then the taps outside the window of length v+1 would be discarded to acquire the TIR filter t of length v+1. Finally, in order to prevent the windowed taps of TIR filter from converging to the trivial solution, i.e. all taps of t are zeros, the energy of t should be normalized to some preset value.

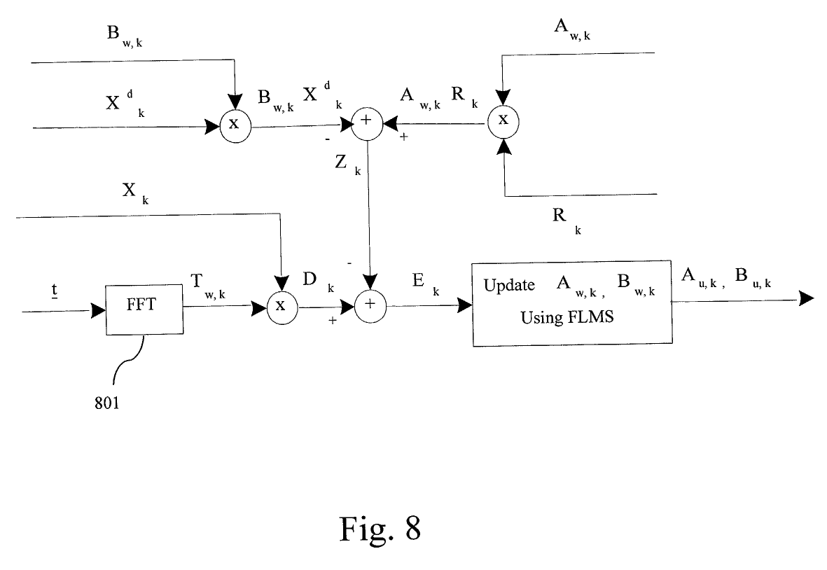

FIG. 8 illustrates the updating step 505 for the feedforward and feedback filters. Similar to the updating step 501, the taps of feedforward, feedback, and TIR filters are transformed by FFTs to their corresponding sets of frequency samples A_{w,k}, B_{w,k} and T_{w,k}. The training data x, the input data of feedback filter X_{d} and the received data r are also transformed into the frequency samples of Xₖ, X^{d}ₖ and Rₖ. Afterward the output frequency samples of feedforward, feedback, and TIR filters could be generated by multiplying A_{w,k} with Rₖ, B_{w,k} with X^{d}ₖ and T_{w,k} with Xₖ,, respectively. The output frequency samples of TIR filter are used as the desired signals and are calculated according to equation [4].

Dₖ=T_{w,k}Xₖ [4]

Let Zₖ denote the difference between the output frequency samples of feedforward filter and feedback filter. It can be expressed as the followig the equation [5]:

Zₖ=A_{w,k}Rₖ−B_{w,k}X^{d}ₖ [5]

Then the error signals would be obtained according to equation [6].

Eₖ=Dₖ−Zₖ [6]

Finally the taps of feedforward and feedback filters in the frequency domain are updated by equation [7] and [8], respectively.

A_{u,k}=A_{w,k}+βEₖR*ₖ [7]

B_{u,k}=B_{w,k}+γEₖ(X^{d}ₖ)* [8]

Herein the parameters of β and γ are the step sizes for updating the feedforward and feedback filters. R*ₖ and (X^{d}ₖ)* are the complex-conjugate values Of Rₖ and X^{d}ₖ.

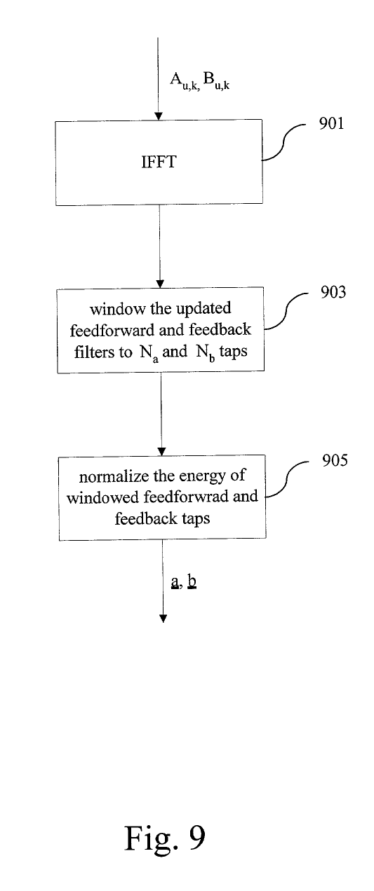

FIG. 9 is a flow chart for depicting the windowing operations 507 on the feedforward and feedback filters. First, the updated frequency taps of feedforward and feedback filters are transformed via IFFTs to the time-domain taps. Then we perform windowing operation on the feedforward and feedback filters to limit them to have Nₐ and N_{b} consecutive taps. The windowing process would be performed circularly to find Nₐ consecutive taps for the feedforward filter (N_{b} consecutive taps for the feedback filter) which has maximum energy inside this window. Finally, in order to prevent the windowed taps of feedforward and feedback filters from converging to the trivial solutions, i.e. all taps of a and b are zeros, the energy of a and b should be normalized to some preset value.

While the invention has been particularly shown and described with reference to the preferred embodiments thereof, it will be understood by those skilled in the art that many alternations and modifications may be made without departing from the spirit scope of the invention.

What is claimed is:

1. A time-domain equalizer system, comprising;
QAM silicers for converting the output of FEQ to the corresponding signal in the QAM constellation for each subcarrier;
an IFFT for inverse fast Fourier transforming data generated by QAM slicers;
a Paraller/Serial converter (P/S) for converting said IFFT output data into a serial form;
a feedforward filter (FF) for whitening the received noises and producing an overall effective channel response such that the output only has causal components;
a feedback filter (FB) for reconstructing the residual causal ISI by using the past decisions;
a delay line for buffering the signals to the input of the feedback filter; and
a switch for connecting the input end of said delay line to a first node.

2. The time-domain equalizer system according to claim 1, wherein said switch further can be connected the input end of said delay line to a second node.

3. The time-domain equalizer system according to claim 1, wherein said feedforward filter continues processing the incoming digital samples at the ADC output and meantime the input end of delay line should be connected to said second node for feeding the last demodulated DMT symbol already here back to the input of said feedback filter during a predetermined time.

4. The time-domain equalizer system according to claim 1, wherein said input end of delay line should be switched to said first node for importing said feedback filter directly from said input of said serial/parallel converter until another DMT symbol be collected at said input of said FEQ.

5. A time-domain equalizer system, comprising
a feedforward filter(FF) for whitening the received noises and producing an overall effective channel response such that the output only has causal components;
a feedback filter(FB) for reconstructing the residual causal ISI by using the past decisions; and
a delay ling for buffering the signals to the input of the feedback filter.

6. A training method of TEQ, comprising the steps
a) fixing the feedforward and feedback filters, and updating a TIR filter in a frequency domain;
b) performing a windowing operation on said TIR in a time domain to limit the taps outside the window of length v+1 to be zero;
c) fixing said TIR and updating said feedforward and feedback filter in said frequency domain; and
d) performing said windowing operations on said feedforward and feedback filters in said time domain to limit them to only Nₐ and N_{b} consecutive non-zero taps, respectively.

7. The training method of TEQ according to claim 6, wherein the step of fixing the feedforward and feedback filters and updating a TIR filter in a frequency domain further comprises the step of transforming the coefficients of feedforward(FF), feedback(FB) and TIR filters into their corresponding sets of frequency domain samples.

8. The training method of TEQ according to claim 6, wherein the step of fixing the feedforward and feedback filters and updating a TIR filter in a frequency domain further comprises the step of transforming the training data, the received data, and the input data of FB into frequency samples.

9. The training method of TEQ according to claim 6, wherein the step of fixing the feedforward and feedback filters and updating a TIR filter in a frequency domain further comprises the step of computing the output frequency samples of FF, FB, and TIR.

10. The training method of TEQ according to claim 6, wherein the desired signals are obtained by the following equation;
Dₖ=A_{w,k}Rₖ−B_{w,k}X^{d}ₖ;
where A_{w,k} and B_{w,k} are corresponding sets of frequency domain samples of feedforward, feedback, and X^{d}ₖ and Rₖ are the frequency samples.

11. The training method of TEQ according to claim 6, wherein the error signals are further obtained as the following equation;
Eₖ=Dₖ−T_{w,k}Xₖ
where T_{w,k} is corresponding sets of frequency samples of TIR, and Xₖ is the input data of feedback filter.

12. The training method of TEQ according to claim 6, wherein the step of fixing the feedforward and feedback filters and updating a TIR filter in a frequency domain further comprises the step of updating the TIR coefficients by the following equation;
T_{u,k}=T_{w,k}+αEₖX*ₖ
where α is the step size, and X*ₖ is the complex-conjugate value of Xₖ

13. The training method of TEQ according to claim 6, wherein the step of performing a windowing operation on said TIR in a time domain to limit the taps outside the window of length v+1 to be zero further comprises the step of transforming the coefficients of updated TIR filter into said time domain taps by IFFT.

14. The training method of TEQ according to claim 6, wherein the step of performing a windowing operation on said TIR in a time domain to limit the taps outside the window of length v+1 to be zero further comprises the step of limiting the taps of TIR filters to v+1 consecutive samples by placing a fixed size window on it.

15. The training method of TEQ according to claim 6, wherein the step of performing a windowing operation on said TIR in a time domain to limit the taps outside the window of length v+1 to be zero further comprises the step of normalizing the energy of windowed TIR filter.

16. The training method of TEQ according to claim 6, wherein the step of fixing said TIR and updating said feedforward and feedback filter in said frequency domain further comprises the step of transforming the coefficients of feedforward(FF), feedback(FB) and TIR filters into their corresponding sets of frequency domain samples.

17. The training method of TEQ according to claim 6, wherein the step of fixing said TIR and updating said feedforward and feedback filter in said frequency domain further comprises the step of transforming the training data, the received data, and the input data of FB into frequency samples.

18. The training method of TEQ according to claim 6, wherein the step of fixing said TIR and updating said feedforward and feedback filter in said frequency domain further comprises the step of computing the output frequency samples of FF, FB, and TIR.

19. The training method of TEQ according to claim 6, wherein the desired signals are obtained by the following equation;
Dₖ=T_{w,k}Xₖ;
where T_{w,k} is corresponding sets of frequency sample of TIR, and Xₖ is the input data of feedback filter.

20. The training method of TEQ according to claim 6, wherein the error signals are further obtained as the following equation;
Eₖ=Dₖ−Zₖ;
where Zₖ is the difference between the output frequency samples of feedforward filter and feedback filter.

21. The training method of TEQ according to claim 6, wherein the step of fixing said TIR and updating said feedforward and feedback filter in said frequency domain further comprises the step of updating the FF coefficients by the following equation;
A_{w,k}=A_{w,k}+βEₖR*ₖ;
where the parameter of β is the step size, and R*ₖ is the complex-conjugate values of Rₖ and X^{d}ₖ.

22. The training method of TEQ according to claim 6, wherein the step of fixing said TIR and updating said feedforward and feedback filter in said frequency domain further comprises the step of updating the FB coefficients by the following equation;
B_{u,k}=B_{w,k}+γEₖ(X^{d}ₖ)*;
where the parameter of γ is the step size.

23. The training method of TEQ according to claim 6, wherein the step of performing said windowing operations on said feedforward and feedback filters in said time domain to limit them to only Nₐ and N_{b} consecutive non-zero taps respectively further comprises the step of transforming the coefficients of updated FF and FB filters into the time domain taps by IFFT.

24. The training method of TEQ according to claim 6, wherein the step of performing said windowing operations on said feedforward and feedback filters in said time domain to limit them to only Nₐ and N_{b} consecutive non-zero taps respectively further comprises the step of limiting the taps FF and FB filters to have Nₐ and N_{b} consecutive taps.

25. The training method of TEQ according to claim 6, wherein the step of performing said windowing operations on said feedforward and feedback filters in said time domain to limit them to only Nₐ and N_{b} consecutive non-zero taps respectively further comprises the step of normalizing the energy of windowed FF and FB filters.
